(19) United States
(12) Patent Application Publication
(10) Pub. No.: US 2015/0029658 A1
(43) Pub. Date: Jan. 29, 2015

(54) SYSTEM FOR COOLING AN INTEGRATED CIRCUIT WITHIN A COMPUTING DEVICE

(71) Applicant: Tactus Technology, Inc., Fremont, CA (US)

(72) Inventors: Micah Yairi, Fremont, CA (US); Craig Ciesla, Fremont, CA (US); Perry George Constantine, Fremont, CA (US); Dave Lind Weigand, Fremont, CA (US)

(73) Assignee: Tactus Technology, Inc., Fremont, CA (US)

(21) Appl. No.: 14/184,460

(22) Filed: Feb. 19, 2014

Related U.S. Application Data
(60) Provisional application No. 61/786,300, filed on Mar. 14, 2013.

(51) Int. Cl. H05K 7/20; G06F 1/16

(52) U.S. Cl. CPC H05K 7/20963; G06F 1/1643; H05K 7/205; H05K 7/20281; H05K 7/20436; H05K 7/20263
USPC 361/679.47

(57) ABSTRACT

One variation of a system for cooling an electrical component within a computing device—including a digital display—includes: an internal heatsink thermally coupled to the integrated circuit and defining a fluid passage including a first end and a second end; a heat exchange layer arranged across a viewing surface of the digital display, including a transparent material, and defining a fluid channel extending across a portion of the digital display, the fluid channel including a fluid inlet coupled to the first end of the fluid passage and a fluid outlet coupled to the second end of the fluid passage; a transparent fluid; and a displacement device configured to circulate the transparent fluid between the internal heatsink and the fluid channel.

### CROSS-REFERENCE TO RELATED APPLICATIONS

This application claims the benefit of U.S. Provisional Patent Application No. 61/786,300, filed on Mar. 14, 2013, which is incorporated in its entirety by this reference.

This application is also related to U.S. patent application Ser. No. 11/969,848, filed on Jan. 4, 2008, U.S. patent application Ser. No. 13/414,589, filed Mar. 7, 2012, U.S. patent application Ser. No. 13/456,010, filed Apr. 35, 2012, U.S. patent application Ser. No. 13/456,031, filed Apr. 35, 2012 (P04-US2), U.S. patent application Ser. No. 13/465,737, filed May 7, 2012, U.S. patent application Ser. No. 13/465,772, filed May 7, 2012, U.S. patent application Ser. No. 14/035,851, filed on Sep. 34, 2013, and U.S. patent application Ser. No. 14/081,519, filed on Nov. 15, 2013, all of which are incorporated in their entireties by this reference.

### TECHNICAL FIELD

This invention relates generally to computing devices, and more specifically to a new and useful system for cooling an integrated circuit 302 in a computing device.

### BRIEF DESCRIPTION OF THE FIGURES

FIG. 1 is a schematic representation of a first system of the invention;

FIG. 2 is a schematic representation of one variation of the first system;

FIGS. 3A and 3B are schematic representations of one variation of the first system;

FIGS. 4A and 4B are schematic representations of one variation of the first system;

FIG. 5 is a schematic representation of one variation of the first system;

FIGS. 6A, 6B, and 6C are isometric representations of variations of the first system;

FIGS. 7A and 7B are schematic representations of one variation of the first system;

FIG. 8 is a flowchart representation of one variation of the first system;

FIGS. 9A and 9B are schematic representations of a second system of the invention;

FIG. 10 is a schematic representation of one variation of the second system;

FIG. 11 is a schematic representation of one variation of the second system;

FIG. 12 is a schematic representation of one variation of the second system; and

FIG. 13 is a schematic representation of one variation of the second system.

### DESCRIPTION OF THE PREFERRED EMBODIMENTS

The following description of the preferred embodiment of the invention is not intended to limit the invention to these preferred embodiments, but rather to enable any person skilled in the art to make and use this invention.

### 1. First System and Applications

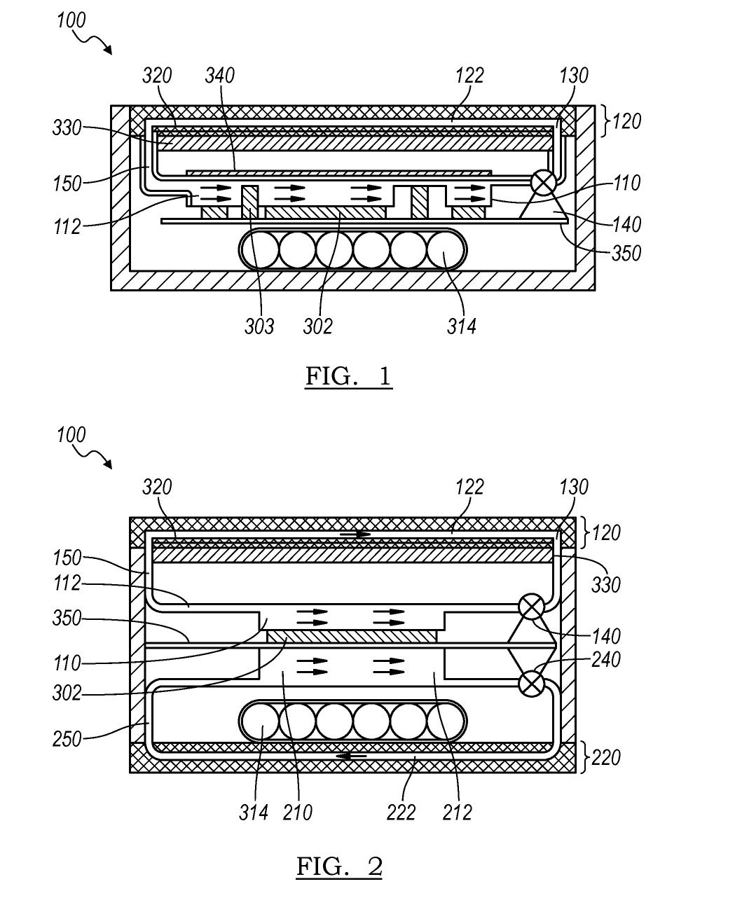

As shown in FIG. 1, a first system 100 for cooling an integrated circuit 302 in a computing device—including a digital display 330—includes: an internal heatsink 110 thermally coupled to the integrated circuit 302 and defining a fluid passage 112 including a first end and a second end; a heat exchange layer 120 arranged across a viewing surface of the digital display 330, including a transparent material, and defining a fluid channel 122 extending across a portion of the digital display 330, the fluid channel 122 including a fluid inlet coupled to the first end of the fluid passage 112 and a fluid outlet coupled to the second end of the fluid passage 112; a transparent fluid 130; and a displacement device 140 configured to circulate the transparent fluid 130 between the internal heatsink 110 and the fluid channel 122.

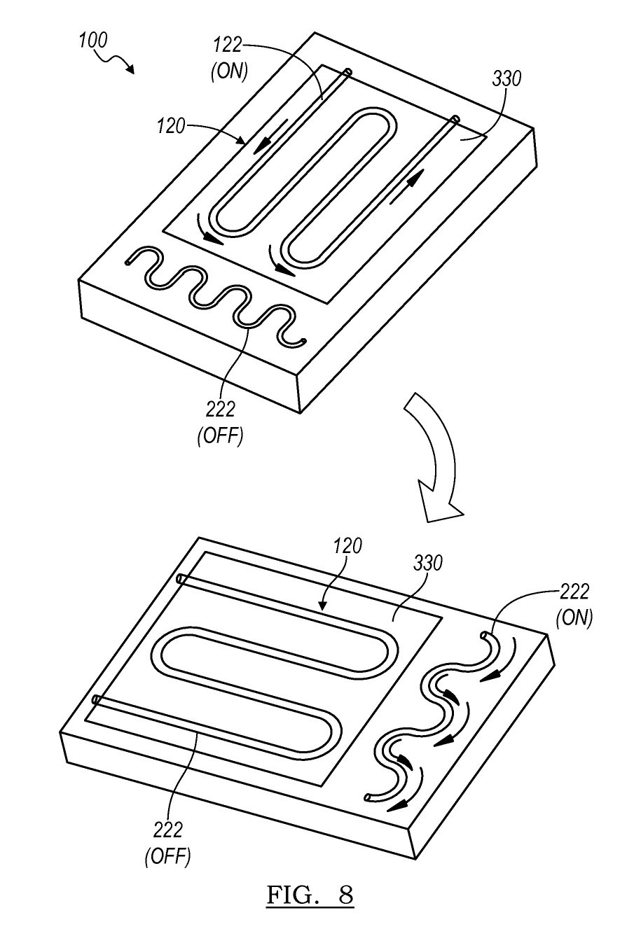

As shown in FIGS. 1 and 8, one variation of first system 100 includes: an internal heatsink thermally coupled to an electrical component 302 within the computing device and defining a fluid passage including a first end and a second end; a heat exchange layer 120 arranged over the digital display 330, including a transparent material, defining a first fluid channel cooperating with the internal heatsink 110 to define a first fluid circuit, and defining a second fluid channel 222 cooperating with the internal heatsink 110 to define a second fluid circuit; a transparent fluid 130; and a displacement device 140 configured to circulate the transparent fluid 130 within the first circuit in response to detected orientation of the computing device in a first position and to circulate the transparent fluid 130 within the second circuit in response to detected orientation of the computing device in a second position.

First system 100 functions to cool one or more electrical components (e.g., a passive circuit element, an integrated circuit 302) within a computing device by pumping fluid from an internal heatsink to a transparent superficial heat exchanger arranged over a digital display 330 of the computing device. For example, first system 100 can transfer heat from a processor, a power supply, a voltage regulator, a display driver, and/or a battery within a mobile computing device to an exterior surface of the device by circulating fluid between the internal heatsink 110 and the heat exchange layer 120. Generally, first system 100 actively transfers heat from local heat sources (i.e., integrated circuits, a display, a battery) within the computing device to a superficial heat exchanger (i.e., on one or more external surfaces of the computing device) by displacing fluid through a closed fluid system (i.e., a fluid circuit) thermally connected to both the heatsink and the heat exchanger. The computing device can be a cellular phone, a smartphone, a tablet, a laptop computer, a digital watch, a personal data assistant (PDA), a personal music (e.g., MP3) player, or any other suitable type of device that includes a display and an electrical circuit that outputs heat during operation.

### 1.2 Internal Heatsink

The internal heatsink 110 of first system 100 is thermally coupled to the integrated circuit 302 and defines a fluid passage including a first end and a second end. Generally, the internal heatsink 110 defines the fluid passage 112 connected at one side to the inlet of the fluid channel 122 and connected at an opposite and/or upstream side to the outlet of the fluid channel 122 such and functions to transfer heat from the integrated circuit 302 (and/or other electrical component within the computing device) into fluid circulating through the fluid passage 112.

In one implementation, the fluid passage 112 defines an elongated channel (e.g., of constant or varying cross-section) that extends across the electrical component 302 within the computing device. For example, the fluid passage 112 can be linear and square in cross-section. In this implementation, the internal heatsink 110 can also define multiple fluid passages that merge into an inlet manifold 124 connected to the fluid inlet at one end and into an outlet manifold 124 connected to the fluid outlet at the opposite or upstream end. Alternatively, the fluid passage 112 can define is a wide and/or deep volume portioned by fins or walls that extend from proximal the fluid inlet to proximal the fluid outlet. For example, the internal heatsink 110 can define a series of internal vanes within the fluid channel 122 adjacent the integrated circuit 302, wherein the vanes extend substantially parallel to a direction of flow of the transparent fluid 130 through the fluid passage 112. However, the internal heatsink 110 can define one or more fluid passages of any other geometry or cross section and directly or indirectly fluidly coupled to the fluid channel 122 in any other suitable way.

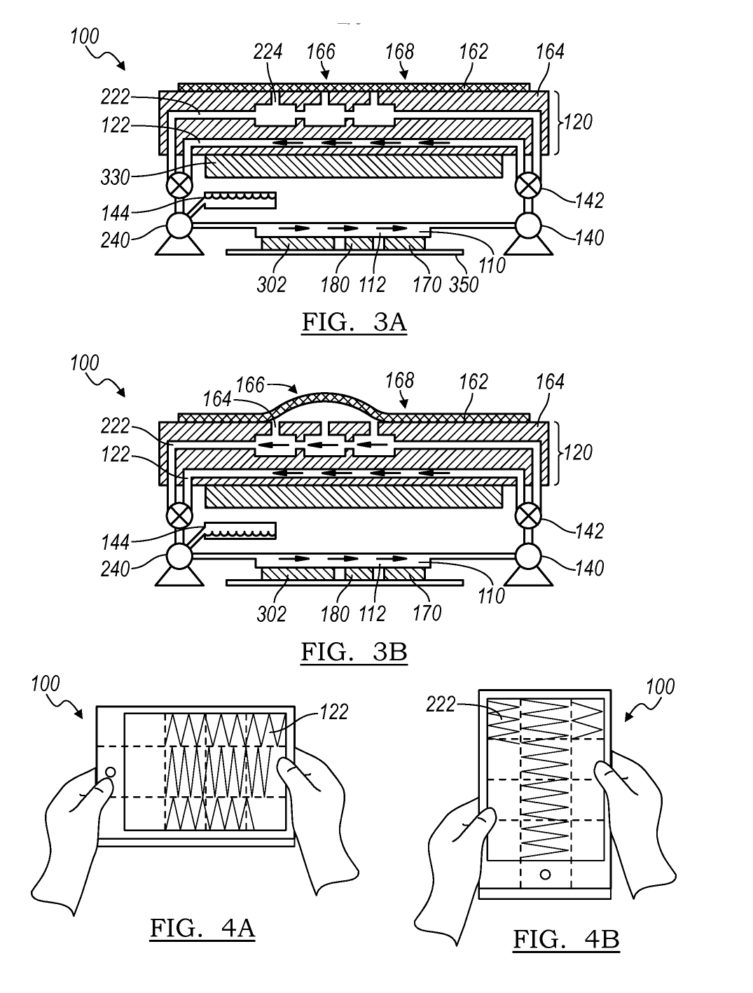

In one implementation in which the integrated circuit 302 or electrical component defines a planar outer surface (e.g., a processor, a solid-state dynamic random-access memory (DRAM), or a battery), the internal heatsink 110 can extend across and directly contact the outer surface of the electrical component 302, as shown in FIG. 1, thereby conducting heat out of the electrical component 302 and into the fluid. The internal heatsink 110 can alternatively be potted adjacent the electrical component 302 or thermally coupled to the electrical component 302 via a thermal interface material (TIM), such as thermal grease or a graphene film. Furthermore, for the electrical component 302 that is mounted on a planar printed circuit board (PCB) 350, a portion of the internal heatsink 110 can be arranged on and/or thermally coupled to the PCB 350, such as on a surface of the PCB 350 opposite and proximal the electrical component 302, as shown in FIG. 3.

The internal heatsink 110 can thus define an enclosed fluid passage that is fluidly isolated from the electrical component 302 and configured to communicate thermal energy from a surface of the electrical component 302 and/or from the PCB 350 into the fluid. In particular, in this implementation, the internal heatsink 110 can define an enclosed structure configured to contact or otherwise thermally couple to an electrical component within the device. For example, the internal heatsink 110 can include stamped copper or aluminum clamshell structures brazed or welded together at a junction to form an enclosed volume with two or more ports configured to fluidly coupled to the fluid inlet and the fluid outlet of the fluid channel 122 in the heat exchange layer 120. In this example, one or both halves of the clamshell can include internal ribs or vanes stamped, molded, welded or otherwise formed into their interior structures, wherein the ribs or vanes form partitions within the enclosed volume to guide fluid flow through the internal heatsink 110. The internal heatsink 110 can be further define a geometry configured to extend over, contact, and/or thermally couple to one or more other electrical components within the computing device, such as a second integrated circuit 302 or passive electrical component arranged on the PCB 350 adjacent the (first) electrical component. For example, the internal heatsink 110 can define a staggered, “stepped,” or “recessed” external surface, wherein facets at different vertical positions across the external surface of the internal heatsink 110 contact (or thermally couple to) electrical components at various heights across the PCB 350, as shown in FIG. 1. Thus, in this example, the displacement device 140 can pump fluid from the output of the fluid channel 122 into the internal heatsink 110 such that the fluid passes over a first facet of the outer surface of the internal heatsink 110 adjacent a first electrical component and then over a second facet of the outer surface of the internal heatsink 110 adjacent a second electrical component 303 to absorb heat from the first and second electrical components in series before returning to the fluid channel 122 in the heat exchange layer 120 to via the fluid inlet to dissipate this thermal energy to the environment. Furthermore, in this implementation, the fluid passage 112 can be linear, convoluted, serpentine (shown in FIG. 6B), or of any other geometry to direct fluid over any number of electrical components at various positions over one or more PCBs within the computing device. Additionally or alternatively, the internal heatsink 110 can define one or more internal ribs or vanes to guide or separate fluid flow through the fluid passage 112.

The internal heatsink 110 can also define an internal geometry configured to limit fluid stagnation. In one example, the internal heatsink 110 defines an internal geometry—such as a vane or interior surface texture—that passively induces turbulence (i.e., mixing) in the fluid. In another example, the internal heatsink 110 includes an active component, such as a secondary pump, configured to actively mix fluid near the electrical component 302. In a further example, the internal heatsink 110 defines chambers, vias, or channels along and/or over the electrical component 302, and the displacement device 140 forces fluid through the channels. However, the internal heatsink 110 can include any other geometry and/or passive or active mixing system to limit stagnation as fluid is circulated through the internal heatsink 110.

In another implementation, the internal heatsink 110 cooperates with a PCB 350 (or other substrate supporting the electrical component 302) within the computing device to define an enclosed volume (with inlet and outlet ports) around the electrical component 302. In this implementation, the internal heatsink 110 and the PCB 350 can cooperate to define the fluid passage 112 such that fluid bathes the electrical component 302 as it moves through the fluid passage 112. For example, the internal heatsink 110 can define a cover arranged over the PCB 350 (or other substrate within the computing device) to encase the electrical component 302, the electrical component 302 thus immersed in the fluid when the fluid passage 112 is flooded. Heat can thus be conducted from the electrical component 302 directly into the fluid. In this implementation, the internal heatsink 110 cover can also cooperate with the PCB 350 to encase and to cool various other active or passive electrical components arranged on the PCB 350. Furthermore, in this implementation, traces and/or vias connecting electrical components on the PCB 350 can be sealed or coated with a non-conductive coating to prevent shorts when the traces and vias are exposed to the fluid, such as for the fluid that includes water. Additionally or alternatively, the fluid system can be filled with a non-conductive fluid, such as alcohol, oil, or an other non-ionic fluid that will not short across traces or other electrical connections on the PCB 350.

Similarly, the internal heatsink 110 can be physically coextensive with a housing of the computing device, wherein the housing defines an enclosed internal cavity (with a inlet and outlet ports to the heat exchange layer 120) that contains the PCB 350, a processor, a battery, a display driver, and/or any other electronic component of the computing device. In this implementation, the cavity can be flooded with fluid such that the electrical components within eh computing device are immersed in fluid, the fluid thus directly conductive thermal energy out of these components as the fluid is circulated between the internal heatsink 110 and the heat exchange layer 120. The internal heatsink 110 can further define internal ribs or vanes that direct fluid flow through fluid passage (i.e., the cavity). As described above, it this implementation, traces, vias, and other exposed conductive components can be coated in a non-conductive coating and/or the transparent fluid 130 can include a non-conductive fluid to prevent shorts across exposed conductive surfaces within the computing device.

However, the internal heatsink 110 can be of any other geometry and can define the fluid passage 112 in any other suitable way and of any other geometry.

The internal heatsink 110 can also be removably or transiently arranged within the computing device. In one example, the internal heatsink 110 is arranged on or is integrated into a battery 310 that is transiently installed in the computing device. In this example, the fluid passage 112 can initiate and terminate at an inlet port and an outlet port, respectively, that couple to the fluid channel 122 when the battery 310 in installed in the device and disconnect from the fluid channel 122 when the battery 310 is removed from the device. In another example, the internal heatsink 110 defines a discrete (i.e., standalone) component with the fluid passage 112 originating and terminating at quick disconnects that transiently engage the fluid inlet and the fluid outlet of the fluid channel 122, respectively, such that the internal heatsink 110 can be removed from the device, serviced or repaired, and reinstalled into the device.

The internal heatsink 110 (and the heat exchange layer 120) can also be flexible. For example, the computing device can include a flexible housing, and the internal heatsink 110 therefore also be flexible such that the internal heatsink 110 can morph with various orientations of the housing.

The housing, cover, clamshell, etc. of the internal heatsink 110 can further functions as an electromagnetic interference (EMI) shield. For example, the internal heatsink 110 can include thin metallic (e.g., copper, aluminum, steel, tin) clamshells brazed together to define the fluid passage 112 such that, when arranged over the PCB 350, the internal heatsink 110 shields EMI transmission from the electrical component 302 from passing out of the device. In another example, the internal heatsink 110 includes conductive tabs or fingers that electrically contact ground traces on the PCB 350 extending off a faceted cover over the PCB 350. Alternatively, the computing device can include an EMI shield 340 interposed between the electrical component 302 (and the PCB 350) and the internal heatsink 110 such that the internal heatsink 110 conducts thermal out of the electrical component 302 (and/or the PCB 350) via the EMI shield 340. Yet alternatively, the internal heatsink 110 can be interposed between the electrical component 302 (or the PCB 350) and an EMI shield 340. Yet alternatively, the transparent fluid 130 can be conductive such that fluid passing through the internal heatsink 110—adjacent integrated and/or passive circuits within the computing device—functions as an EMI shield to shield EMI transmission out of the device.

### 1.3 Heat Exchange Layer

The heat exchange layer 120 is arranged across a viewing surface of the digital display 330, includes a transparent material, and defines a fluid channel 122 extending across a portion of the digital display 330, wherein the fluid channel 122 includes a fluid inlet coupled to the first end of the fluid passage 112 and a fluid outlet coupled to the second end of the fluid passage 112. Generally, the heat exchange layer 120 defines a (superficial) fluid-air heat exchanger that communicates fluid through one or more enclosed channels over an exterior surface of the computing device to dissipate heat—absorbed from the electrical component 302 at the internal heatsink 110—to the environment. In particular, the displacement device 140 moves fluid through the internal heatsink 110, across the electrical component 302 to absorb fluid, then through the fluid channel 122 where heat is dissipated to ambient, and the fluid thus returns—now cooled—to the internal heatsink 110 to again absorb heat from the electrical component 302. The fluid channel 122 in heat exchange layer, the fluid passage 112 in the internal heatsink 110, and the displacement device 140 can thus device a closed fluid circuit. Furthermore, in one implementation of first system 100 described below, the heat exchange layer 120 defines a first fluid channel 122 cooperating with the internal heatsink 110 to form a first fluid circuit and further defines a second fluid channel 222 cooperating with the internal heatsink 110 to form a second fluid circuit, such as described below. However, the substrate can define any other number of discrete fluid channels or discrete sets of fluid channels that cooperate with any one or more internal heatsinks to define corresponding fluid circuits.

The heat exchange layer 120 is arranged over the display 330 of the computing device, as shown in FIGS. 1 and 3. The display 330 can be a digital display 330, such as an LED-backlit LCD display, an e-ink display, or a plasma display. The display 330 can also be a touchscreen, such as a digital display 330 coupled to capacitive or resistive touch sensor. However, the display 330 can be any other suitable type of display. The heat exchange layer 120 can also be arranged over the display 330 with a discrete touch sensor 320 layer interposed therebetween. The heat exchange layer 120 can therefore be translucent or substantially transparent to enable transmission of light (e.g., an image) from the display 330 to a user or viewer. For example, the heat exchange layer 120 can include one or more substantially transparent layers of amorphous glass, sapphire, silicone, acrylic, and/or polycarbonate. The heat exchange layer 120 also defines the fluid channel 122 that communicates fluid laterally, such as across the display 330 and/or a bezel adjacent the display 330. The heat exchange layer 120 can therefore be selected from a material(s) with an index of refraction substantially similar to that of the fluid such that the fluid channel 122(s) is substantially imperceptible to a user, such as from a viewing distance of twelve inches between the user's eyes and the computing device. For example, the heat exchange layer 120 can include a transparent elastomer (e.g., silicone, polycarbonate) layer of a first refractive index at a wavelength of light, and the transparent fluid 130 can be an oil of a second refractive index substantially similar to the first refractive index at the wavelength of light. The heat exchange layer 120 can also be of a composite material with multiple layers of different indices of refraction, a single layer of index of refraction that varies with depth, one or more layers with a designed Abbe number, etc. to substantially match an optical property of the fluid such that a junction between the fluid and the fluid channel 122 is substantially imperceptible to the naked (human) eye at a standard viewing distance. The heat exchange layer 120 can also define the fluid channel 122 that is of a substantially small cross-sectional area such that the fluid channel 122 is difficult to distinguish visually. For example, the fluid channel 122 can be a microfluidic fluid channel of substantially high aspect ratio, its length substantially greater than its width (or diameter).

In one implementation, the heat exchange layer 120 includes a rigid substrate, such as of silicate glass, alkali-aluminosilicate glass, aluminum nitride, or sapphire, that defines an exterior surface of the device. In this implementation, an open channel can be etched, machined, molded, or otherwise formed in an internal surface of the substrate, which is then bonded over the display 330 or other a touch sensor layer. The substrate can then be bonded over the display 330 or the touch sensor layer, which closes the open channel to define the fluid channel 122. Alternatively, an open channel can be formed in a glass substrate, and a glass or elastomer closing panel can be bonded over the substrate to close the open channel, thereby forming the fluid channel 122. In this implementation, first system 100 can further include a pressure relief valve arranged between the internal heatsink 110 and the heat exchange layer 120 and configured to open in response to fluid pressure in the fluid channel 122 exceeding a threshold pressure. In particular, the pressure relief valve can trip when a threshold pressure is reached within the fluid channel 122, thereby releasing fluid pressure within the fluid channel 122 to prevent the heat exchange layer 120 from cracking or shattering due to excessive fluid pressures within the fluid channel 122. Additionally or alternatively, the fluid can exhibit a substantially low coefficient of thermal expansion, or the displacement device 140 can manipulate a flow rate of fluid through the fluid channel 122 based on an output of a pressure sensor fluidly coupled to the fluid channel 122 and/or to the fluid passage 112.

In another implementation, the heat exchange layer 120 includes an elastomer outer sublayer bonded to a substrate that is arranged over the display 330 (and/or the touch sensor 320). For example, the heat exchange layer 120 can define an elastic substrate defining an open channel with vias at each end (fluidly coupled to the internal heat sink and/or to the displacement device 140), and an elastic outer sublayer can be bonded across the substrate to close the open channel, thereby forming the fluid channel 122. For example, the substrate and the outer sublayer can be assembled as described in U.S. patent application Ser. No. 14/035,851, filed on Sep. 34, 2013, which is incorporated in its entirety by this reference. However, the heat exchange layer 120 can include any suitable material, can define any suitable external or fluid channel geometry, and/or can be manufactured in any suitable way, such as described in U.S. patent application Ser. No. 11/969,848 and/or U.S. patent application Ser. No. 13/414,589, which are incorporated in there entireties herein by this reference.

In one implementation, the heat exchange layer 120 defines a set of connected fluid channels. For example, the heat change layer can define a set of parallel fluid channels, an inlet manifold 124, and an outlet manifold 126, wherein each fluid channel in the set of fluid channels originates at the inlet manifold 124 and terminates at the outlet manifold 126, as shown in FIG. 6A. In this example, the inlet manifold 124 and the outlet manifold 126 can be arranged over a bezel area of the computing device adjacent a viewing area of the digital display 330, and the fluid channels can extend from a first side of the display 330 (e.g., proximal a left side of the display 330 when viewed in a landscape orientation) to a second side of the display 330 (e.g., proximal a right side of the display 330 when viewed in a landscape orientation), as shown in FIG. 6A. The heat exchange layer 120 can define fluid channels of substantially linear and of substantially constant and similar cross-sectional areas. The heat exchange layer 120 can additionally or alternatively define one or more fluid channels of a serpentine (shown in FIG. 6B), curved, zigzag or other geometry and/or of constant or varying cross-section. For example, the heat exchange layer 120 can define fluid channels with round, square, rectilinear, polygonal, or elliptical cross-sections. However, the heat exchange layer 120 can define one or more fluid channels of any other form, geometry, or cross-section.

The heat exchange layer 120 can further define a second set of fluid channels that extend—substantially perpendicular to the first second of fluid channels—from a third side of the display 330 (e.g., proximal a top side of the display 330 when viewed in a portrait orientation) to a fourth side of the display 330 (e.g., proximal a bottom side of the display 330 when viewed in a portrait orientation), as shown in FIG. 6C. For example, the heat exchange layer 120 can define a second fluid channel 222 including a second fluid inlet and a second fluid outlet fluidly coupled to the internal heatsink 110, the second fluid channel 222 extending across the digital display 330 with the second fluid inlet proximal a first long edge of the rectangular viewing area and the second fluid outlet proximal a second long edge of the rectangular viewing area opposite the first long edge. In this example, the heat exchange layer 120 can similarly define a second set of parallel fluid channels connected to a second inlet manifold 124 and to a second outlet manifold 126. In this implementation, the first set of fluid channels can be set at a first (constant) depth in the heat exchange layer 120 and the second fluid channel 222 or the second set of fluid channels can be set at a second depth in the heat exchange layer 120 different from the first depth, such as shown in FIG. 6C. Alternatively, the heat exchange layer 120 can define the first and second sets of fluid channels at substantially similar or at varying depths such that fluid channels overlap but do not join at intersections.

The fluid channel 122 (and/or each fluid channel in a set of fluid channels) can extend from proximal one edge of the display 330 (e.g., at the inlet) to an opposite edge of the display 330 (e.g., at the outlet). The fluid channel 122 can also extend beyond the display 330, such as into a display border or bezel area. The fluid channel 122 can also originate and terminate at or near a same end (or edge) of the display 330 or at or near any other region(s) of the display 330. For example, the fluid channel 122 can extend linearly from the inlet at a first end of the display 330 toward an opposite end of the display 330, define two ninety-degree bends, and return to the first edge where it couples to the fluid outlet. Alternatively, the first fluid channel 122 can extend over the viewing area of the display 330, and the second fluid channel 222 can extend over a bezel adjacent a viewing area of the display 330. For example, the second channel can define a serpentine path over one rectilinear region of the bezel area, and the heat exchange layer 120 can define a set of parallel fluid channels connected at each to common manifolds.

The heat exchange layer 120 can similarly define multiple fluid channel sets, each arranged over a discrete region or over intersecting regions of the display 330. For example, the heat exchange layer 120 can define each fluid channel set over one of several discrete (rectilinear) regions of the display 330, the discrete regions arranged in a grid pattern (e.g., a 3×6 grid array) across the display 330, as shown in FIGS. 4A and 4B. In this example, first system 100 can selectively pump fluid through fluid channels in the heat exchange layer 120 based on where a user places his hands to hold the computing device. For example, the displacement device 140 can shut off fluid flow to fluid channels sets adjacent a user's hands and fingers and redirect fluid flow to other fluid channels in the heat exchange layer 120 not adjacent the user's hands and fingers, such as shown in FIGS. 4A and 4B. In this example, first system 100 can further include a processor 170 configured to convert touches or inputs on a touch sensor 320 over the display 330 to a predicted placement of the user's hands and fingers on the device and, based on this predicted placement, set a series of valves between the fluid channels and the internal heatsink 110 to selectively move heated fluid to particular regions of the heat exchange layer 120 away from predicted current human contact points. Additionally or alternatively, in this example and as described below, the processor 170 can interface with a motion sensor (e.g., an accelerometer, a gyroscope) to detect an orientation of the device (e.g., a portrait orientation, a landscape orientation)—which can be associated with human contact points over the device—and set valves between the fluid channel 122 and the fluid passage 112 and/or the displacement device 140 accordingly. However, the heat exchange layer 120 can define any other number of fluid channels in any one or more fluid channel sets in any other form or geometry or over any one or more portions of any geometry over the display 330.

In one variation, first system 100 further includes a second heat exchange layer 220 arranged across rear exterior surface of the computing device opposite the digital display 330, wherein the second heat exchange layer 220 defines a second fluid channel 222 fluidly coupled to the first fluid channel 122. In this variation, the second heat exchange layer 220 can be substantially similar to the heat exchange layer 120, such as of a similar geometry and of similar (e.g., transparent) materials with the second fluid channel 222 fluidly coupled to the internal heatsink 110. However, the second heat exchange layer 220 can be of any other material and/or geometry. Thus, the displacement device 140 can simultaneously displace fluid from the internal heatsink 110 into the first fluid channel 122 in the external heat exchange layer and into the second fluid channel 222 in the second external heat exchange layer, thereby distributing heat to “front” and “rear” exterior surfaces of the computing device to cool one or more electrical components within. Additionally or alternatively, the displacement device 140 can selectively circulate between the internal heatsink 110 and the first fluid channel 122 and between the internal heatsink 110 and the second fluid channel 222, as described below.

In another implementation of the apparatus, the heat exchange layer 120 includes a substrate and an elastomer layer, wherein the substrate defines an open trough extending across a surface opposite the digital display 330, wherein the elastomer layer includes a peripheral region 168 coupled to the substrate and a deformable region 166 arranged over the open trough to define the fluid channel 122, and wherein the deformable region 166 is configured to expand outwardly above the peripheral region 168 in response to increased fluid pressure within the fluid channel 122. Generally, in this implementation, the deformable region 166 functions to deform outwardly, thereby increasing the outer surface area of the hear exchange layer and increasing heat transfer out of the fluid into the environment. For example, the substrate can define a series of parallel linear troughs connected at each end to a manifold, and the elastomer layer can define a deformable region 166 above each trough such that, when fluid pressure within the corresponding fluid channels rises above ambient (i.e., barometric) pressure, the deformable regions expand to form fins or ribs across the heat exchange layer 120. Then, when fluid pressure drops to or below ambient, the deformable regions can retract back to flush with the peripheral region 168 such that the heat exchange layer 120 is of a substantially uniform thickness across, thereby minimize optical distortion of light output by the display 330 below. The substrate can also define a support member arranged over the troughs to prevent displacement of a deformable region 166 into the trough, such as described in U.S. patent application Ser. No. 13/414,589. In this implementation, the heat exchange layer 120 can define the deformable region 166 across the display 330, around a perimeter of the display 330, and/or over a bezel area adjacent the display 330. In this variation of first system 100 that includes a second heat exchange layer 220, the second heat exchange layer 220 can additionally or alternatively include second a substrate and a second elastomer layer, wherein the second substrate defines a second open trough, wherein the second elastomer layer includes a second peripheral region 168 coupled to the second substrate and a second deformable region 166 arranged over the second open trough to define a second fluid channel 222, and wherein the second deformable region 166 is configured to expand outwardly above the second peripheral region 168 in response to increased fluid pressure within the second fluid channel 222.

In the foregoing implementation, a deformable region 166 can be substantially bistable, wherein the deformable region 166 remains substantially flush with the peripheral region 168 in a retracted setting until a threshold fluid pressure is reached within the fluid channel 122, at which point the deformable region 166 transitions into the expanded setting until fluid pressure again drops below the threshold pressure. Alternatively, the deformable region 166 can expand proportionally with fluid pressure in the fluid channel 122, and the displacement device 140 can interface with a pressure sensor coupled to the fluid channel 122 to regulate fluid pressure within the fluid channel 122(s) and therefore the height of the corresponding deformable region 166(s) above the peripheral region 168.

### 1.4 Fluid Junction

As shown in FIG. 1, one variation of first system 100 includes a fluid junction 150 configured to fluidly couple the internal heatsink 110 to the heat exchange layer 120. Generally, the fluid junction 150 functions to couple the outlet port of the internal heatsink 110 to the fluid inlet of the heat exchange layer 120 and to couple the fluid outlet of the heat exchange layer 120 to the inlet port of the internal heatsink 110, thereby creating a closed fluid loop through which the transparent fluid 130 flows to adsorb heat from one or more electrical components within the device and to release thermal energy to the environment. In one implementation, the fluid inlet and the fluid outlet of the heat exchange layer 120 can define vias through the substrate of the heat exchange layer 120, as described in U.S. patent application Ser. No. 14/035,851, and first system 100 and include one fluid junction 150 that connects each via to a corresponding end of the fluid passage 112 within the internal heatsink 110. For example, the fluid junction 150 can include a soft coupling, such as a silicone, PETG, or urethane coupling, or the fluid junction 150 can include a rigid coupling, such as including a male and a female coupling that rigidly connect when the computing device assembled with first system 100.

The fluid junction 150 can further interface with the displacement device 140. In one implementation, the displacement device 140 is arranged in line with the fluid junction 150 at the fluid inlet side of the internal heatsink 110 or at the fluid outlet side of the internal heatsink 110, as shown in FIG. 1. The fluid junction 150 can also interface with one or more valves, a second heat exchanger layer, and/or additional displacement devices, as shown in FIGS. 3A and 3B.

The fluid junction 150 can also include a septum or a filling port to enable a user or machine to fill first system 100 with fluid. The filling port can pass through a housing of the computing device for quick access by a user or machine, or the filling port can be arranged inside the computing device, thus requiring disassembly of a portion of the computing device to fill, empty, and/or change fluid within first system 100. The fluid junction 150 can similarly include a drainage port to allow a user or machine to remove fluid from first system 100. As described above, the fluid junction 150 can also include quick disconnects to enable various components, such as the displacement device 140, the internal heatsink 110, etc. to be removed, serviced, repaired, reinstalled, and/or replaced.

### 1.5 Displacement Device

The displacement device 140 is configured to circulate the transparent fluid 130 between the internal heatsink 110 and the external heat exchange layer. Generally, the displacement device 140 functions to actively move fluid through the enclosed fluid system to redistribute heat from a heat source with the computing device to a surface of the computing device such that one or more electrical components inside the computing device may be cooled by dissipating heat to the environment.

The displacement device 140 can be a positive displacement pump that pushes (or pulls) fluid in a single direction, such as described in U.S. patent application Ser. No. 13/414,589. Alternatively, the displacement device 140 can be an intermittent pump, such as described in U.S. patent application Ser. No. 14/081,519. Yet alternatively, the displacement device 140 can cooperate with the internal heatsink 110 to define a passive heat pipe. The displacement device 140 can cooperate with the internal heatsink 110 and the heat exchange layer 120 to form a thermosiphon that passively circulates heated fluid from proximal the electrical component 302 to the heat exchange layer 120 and return cooled fluid from the heat exchange layer 120 back to the fluid passage 112 adjacent the electrical component 302. The displacement device 140 can therefore directly act on (i.e., contact with) the fluid. Alternatively, the displacement device 140 can indirectly displace fluid within first system 100, such as by manipulating a reservoir containing the fluid. For example, the displacement device 140 can expand and retract a bladder with unidirectional (e.g., check) valves at two ports connected to the bladder to circulate fluid from the bladder into the fluid passage 112, then the fluid channel 122, and back into the bladder, or vice versa.

However, the displacement device 140 can be any other suitable type of active or passive pump and can circulate fluid through first system 100 in any other suitable way. First system 100 can also include any number of similar or different pumps to move fluid through the computing device.

### 1.6 Dynamic Tactile Layer

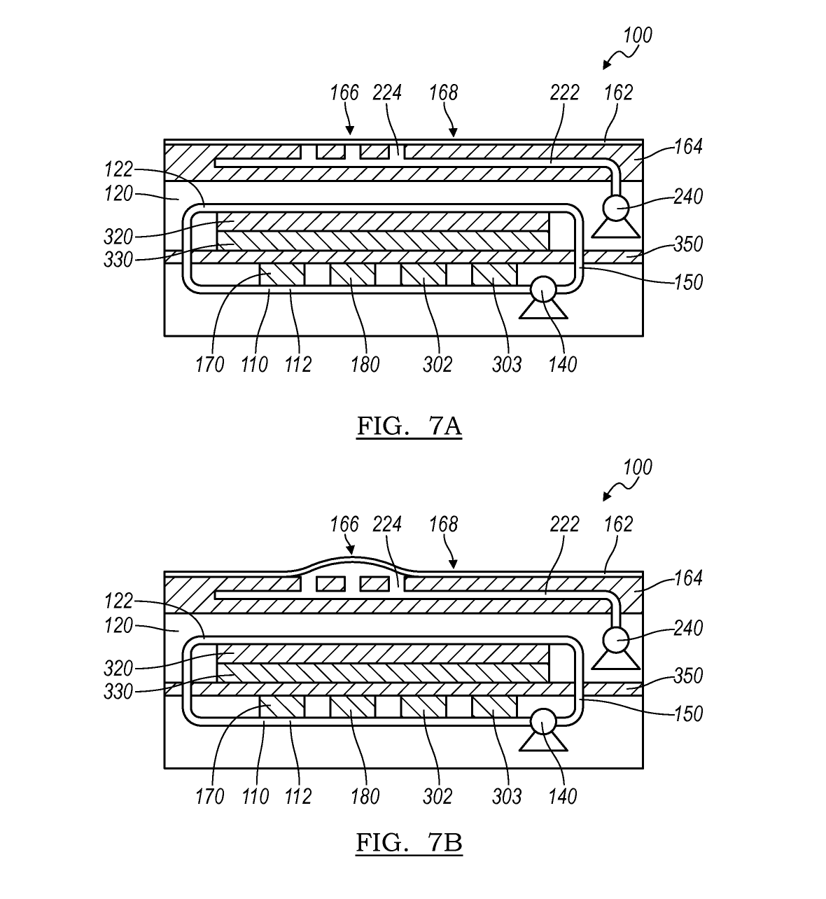

As shown in FIGS. 3A, 3B, 7A, and 7B, one variation of first system 100 further includes: a substrate 164 of a substantially transparent material, arranged over the heat exchange layer 120 opposite the display 330, and defining a second fluid channel 222 and a fluid conduit 224 fluidly coupled to the second fluid channel 222, the second fluid channel 222 fluidly decoupled from the fluid channel 122; a tactile layer 162 of a substantially transparent material and including a peripheral region 168 coupled to the substrate 164 and a deformable region 166 arranged over the fluid conduit 224 and disconnected from the substrate 164; and a second displacement device 240 coupled to the second fluid channel 222 and configured to displace fluid through the fluid channel 122 to transition the deformable region 166 from a retracted setting (shown in FIG. 3A) to an expanded setting (shown in FIG. 3B), the deformable region 166 elevated above the peripheral region 168 in the expanded setting.

Generally, in this variation, first system 100 defines a deformable region 166 over the display 330 of the computing device, wherein the deformable region 166 can be intermittently and selectively expanded to provide occasional tactile guidance over the display 330, such as described in U.S. patent application Ser. No. 13/414,589. In one implementation, the substrate 164 and the tactile layer 162 are arranged over the heat exchange layer 120 such that thermal energy passes from the fluid into the heat exchange layer 120 and then into the substrate 164 and the tactile layer 162 before dissipating into the environment (or into a user or other surface in contact with the computing device), such as shown in FIGS. 7A and 7B. Alternatively, the substrate 164 and the tactile layer 162 can be physically coextensive with the heat exchange layer 120, wherein both the fluid channel 122 coupled to the internal heat sink and the second fluid channel 222 in communication with deformable region 166 are defined within the substrate 164, such as shown in FIGS. 3A and 3B. In this implementation, the (first) fluid channel and the second fluid channel 222 can be discrete and fluidly decoupled, the first fluid channel 122 coupled to the displacement device 140 to circulate fluid between the fluid channel 122 and the internal heatsink 110, and the second fluid channel 222 coupled to the second displacement device 240 to communicate (a discrete volume of) fluid toward and away from the deformable region 166 to expand and retract the deformable region 166, respectively. However, the substrate 164 and the tactile layer 162 can be arranged and/or defined within first system 100 in any other suitable way.

### 1.7 Valve

As shown in FIGS. 3A and 3B, one variation of first system 100 further includes a valve 142 configured to control fluid flow through first system 100. For example, in the implementation described above in which the heat exchange layer 120 defines two discrete fluid channel sets, the valve 142 can be arranges at a junction between the two fluid channel sets to selectively shut off flow into one or the other fluid channel set.

In one implementation in which the computing device includes a dynamic tactile layer 162, as disclosed in U.S. patent application Ser. No. 13/414,589, first system 100 can include a valve 142 between a cooling portion of first system 100 and a reconfigurable button of the dynamic tactile layer 162, as shown in FIGS. 3A and 3B. For example, the heat exchange layer 120 can be physically coextensive with the dynamic tactile layer 162, wherein the displacement device 140 creates a pressure differential that displaces fluid through the enclosed fluid system, and wherein a first pair of valves open at each end of a subset of fluid channels to allow fluid to pass through the subset of fluid channels over a first portion of the display 330 to dissipate heat in the fluid, and wherein one valve opens and another valve closes in a second pair of valves to enable fluid to collect in a respective subset of fluid channels, thereby outwardly deform a deformable region 166 of the dynamic tactile layer 162 fluidly coupled to the subset of fluid channels. In this example, the fluid channel 122 of first system 100 can be physically coextensive with a fluid channel of the dynamic tactile layer 162. Furthermore, in this example, the displacement device 140 can displace fluid in the fluid system to both (e.g., simultaneously) redistribute heat through the computing device and manipulate a dynamic tactile overlay on the digital display 330.

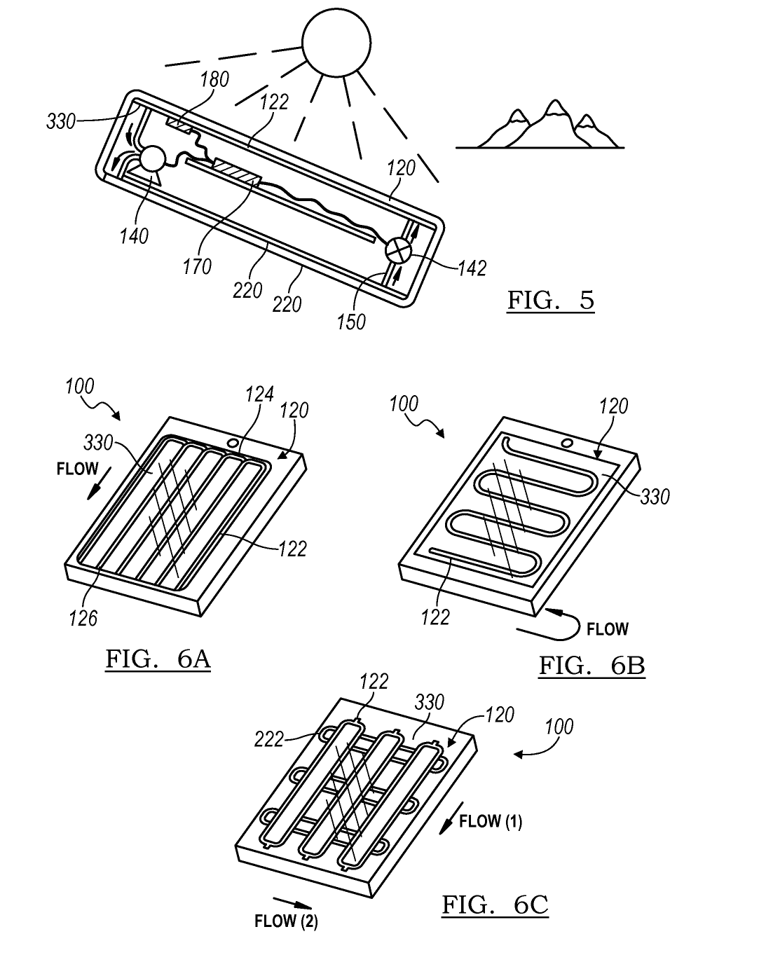

A valve 142 in the fluid system can be a bi-state valve that is either open or closed, a tri-state valve that can select between two fluid passages and close fluid flow completely between the two fluid passages, or any other suitable type of valve. However, the valve 142 can also be substantially imperfect, i.e., reducing fluid flow by less than 100% or leaking in the presence of a pressure differential across the valve 142. In one example implementation, the heat exchange layer 120 includes a discrete front heat exchange region over the digital display 330, bezel area, discrete side heat exchangers, and/or a discrete rear heat exchange region on the back of the computing device (opposite the digital display 330), each discrete heat exchange region including one or more fluid channels. For example, inlets of the front and rear heat exchange regions can be connected via an imperfect bi-state valve that, in a first position, allows 80% of fluid flow to enter the front heat exchange region and 30% to enter the rear heat exchange region when the computing device is laying face-up on a surface. Furthermore, in a second position, the imperfect bi-state valve can allow 30% of fluid flow to pass through the front heat exchange region and 80% to pass through the rear heat exchange region when the digital display 330 is experiencing solar heating during outdoor user (e.g., as determined by elevated display temperatures measured by a thermistor 180 thermally coupled to the display 330), as shown in FIG. 5. As in this example implementation, first system 100 can implement preferential (e.g., 80%) displacement of heated fluid to certain regions of the fluid system with imperfect valves and still achieve substantial cooling functionality. In particular first system 100 adequately distribute heat from the electrical component 302 to the surface of the computing device without necessitating expensive and/or large valves that are capable of withholding fluid leaks up to fractions of or more psi of fluid pressure.

In another implementation in which the displacement device 140 is an intermittent pump as described in U.S. Patent Application No. 61/727,083, first system 100 can include a tri-state valve or two inversely-controlled bi-state valves that oscillate between states as the displacement device 140 transitions between positive pressure and vacuum states such that fluid is drawn through the closed fluid loop in a single direction as the displacement device 140 opens and closes. However, first system 100 can include any other number of valves arranged in any other suitable way to control fluid flow through first system 1000. However, first system 100 can include any number of valves arranged in any way throughout the closed fluid loop.

### 1.8 Processor

As shown in FIG. 5, one variation of first system 100 further includes a processor 170 that controls distribution of fluid through the internal heatsink 110 and the heat exchange layer 120 to cool the electrical component 302. Generally, the processor 170 functions to control the displacement device 140 and/or one or more valves in first system 100 based on various outputs from one or more sensors in the computing device, such as an accelerometer, a gyroscope, a light sensor or camera, a thermistor 180 or temperature sensor 180, a specific absorption rate (SAR) sensor, a power meter, and/or a near-body proximity sensor. Sensor-based cooling architecture can thus enable direct, real-time detection of human proximity and device orientation such that the processor 170 can dynamically control various fluid valves to direct heated fluid away from portions of the computing device currently in contact with a user. The processor 170 can additionally or alternatively control components of first system 100 based on a setting (e.g., clock speed) of the computing device. The processor 170 can be a standalone controller or physically coextensive with an electrical component (e.g., CPU) within the computing device.

In one implementations of the displacement device 140 that actively circulates fluid through first system 100, the displacement device 140 can be configured to operate at a constant (i.e., single) flow rate or at a variable flow rate. For example, first system 100 can include a processor 170 that collects fluid pressure data from a pressure sensor coupled to the fluid channel 122 and/or power draw data from a motor driver connected to the displacement device 140 to determine a fluid pressure within first system 100, and the processor 170 can thus implement feedback control to adjust power to the flow rate of fluid through first system 100 accordingly by modifying an amount of power supplied to the displacement device 140. Similarly, the processor 170 can interface with one or more thermal sensors arranged throughout the device to implement closed loop feedback to adjust a flow rate (e.g., proportional to power consumption of the displacement device 140) through first system 100 to achieve a target temperature at one or more locations within the computing device. For example, the processor 170 can implement proportional-integral-derivative (PID) control to adjust a flow rate through the fluid circuit based on a temperature at the electrical component 302, a temperature gradient across the digital display 330, and a fluid pressure within the fluid circuit. In particular, in this example, the processor 170 can control the displacement device 140 to circulate the transparent fluid 130 between the internal heatsink 110 and the fluid channel 122 at a working pressure corresponding to a measured temperature of the electrical component 302 (e.g., the integrated circuit 302).

In one implementation, the heat exchange layer 120 includes multiple discrete fluid channels (or discrete fluid channel sets), each defining a heat exchange region over the digital display 330. For example, the viewing area of the display 330 can be rectangular, and the heat exchange layer 120 can include a heat exchange region along each short end of the viewing area defining a first fluid circuit with the internal heatsink 110 and the heat exchange layer 120 can include a heat exchange region along each long end of the viewing area defining a second fluid circuit with the internal heatsink 110. The processor 170 can thus interface with an accelerometer and/or gyroscope (or other motion or position sensor) within the computing device to detect an orientation of the computing device, and when the processor 170 detects that the computing device is in a portrait orientation (shown in FIG. 4B), the processor 170 can set a state of one or more valves within first system 100 to close fluid flow through the second fluid circuit and to open fluid flow through the first fluid circuit, thereby limiting heat dissipation at regions over the digital display 330 likely to be in contact with the user's hand(s) in the portrait orientation. Similarly, when the processor 170 detects that the computing device is in a landscape orientation (shown in FIG. 4A), the processor 170 can set the state of one or more valves in first system 100 to close fluid flow through the first fluid circuit and to open fluid flow through the second fluid circuit, thereby limiting heat dissipation at regions over the digital display 330 likely to be in contact with the user's hand(s) when the computing device is in the landscape orientation.

Additionally or alternatively, the processor 170 can interface within one or more sensors within the computing device to determine a current orientation of the device, and the processor 170 can subsequently set the state of one or more valves with first system 100 to distribute fluid flow there through to meet a target heat flux through convection from surfaces of the computing device. For example, the processor 170 can set valve states within first system 100 to preferentially distribute fluid to substantially vertical and upward facing surfaces of the computing device, such as the front and back surfaces of the device when the device is held substantially upright and the front and sides of the devices when the device is placed face-up on a horizontal surface. In particular, in this example, first system 100 can include multiple heat exchange layers, such as over the device's digital display 330, over a rear surface of the device, and/or over sides of the device, such as described above, all of which can be fluidly coupled to one or more electrical components within the device via an internal heatsink and a valve 142, and the processor 170 can selectively open and close valves in first system 100 to distribute fluid throughout first system 100 according to a desired temperature distribution and/or a heat flux across surfaces of the computing device. Similarly, the processor 170 can interface with temperature sensors arranged throughout the computing device to measure and/or estimate a temperature distribution across surfaces of the device, and the processor 170 can manipulate valves and/or the displacement device 140 to distribute fluid flow through first system 100 to achieve a substantially uniform temperature (or other desired temperature gradient) across surfaces of the device.

The processor 170 can further interface with a touch sensor 320 within the device to detect regions on the device in contact with the user, and the processor 170 can set one or more valves within first system 100 to move heated fluid from the internal heatsink 110 through fluid channels removed from regions of contact with the user. For example, the processor 170 can interface with the touch sensor 320, a proximity sensor, and/or any other sensor within the computing device to determine that the device is in the user's pant pocket with the display 330 facing the user's skin, and the processor 170 can thus close fluid flow to the heat exchange layer 120 over the display 330 and reroute heated from the internal heatsink 110 to the second heat exchange layer 220 arranged over the back of the computing device opposite the display 330. In another example, the processor 170 can interface with various proximity sensors through the device to determine placement of a user's hand and/or fingers on the computing device, and the processor 170 can control one or more valves within first system 100 to route fluid flow away from the user's hand and/or fingers, thereby limiting or preventing dissipation of heat from the electrical component 302 into the user's hand and/or fingers. The processor 170 can also store and/or access a history of device orientation and proximity events and further implement machine learning to improve response to various use scenarios of the particular mobile computing device.

In the foregoing implementations, additional fluid channels and/or heat exchange layers can be fluidly coupled to a common internal heatsink, such as via one or more valves, and the processor 170 can manipulate a position of the one or more valves to selectively distribute fluid throughout first system 100. Alternatively, each additional fluid channels and/or heat exchange layers can be fluidly coupled to a discrete internal heatsink and to a discrete displacement device, and the processor 170 can selectively power various displacement devices to selectively distribute fluid throughout first system 100, such as according to any of the methods or techniques described above. In one example, the internal heatsink 110 is arranged on one side of the electrical component 302 and cooperates with the heat exchange layer 120 arranged over the digital display 330 and the displacement device 140 to define a first closed fluid loop, and a second internal heatsink on an opposite side of the electrical component 302 cooperates with a second heat exchange layer 220 arranged on the back surface of the computing device and a second displacement device 240 to define a second closed fluid loop, wherein the first closed fluid loop and the second closed fluid loop are discrete and separately controlled by the processor 170. In this example, the processor 170 can independently control components of each closed fluid loop, such as based on computing device orientation or user hand placement on the computing device. However, first system 100 can include any number of internal heatsinks, heat exchange layers, sensors, valves, and/or displacement devices arranged in any other suitable way.

In another implementation, first system 100 includes the heat exchange layer 120 over the digital display 330, the second heat exchange layer 220 over the back of the computing device opposite the display 330 (shown in FIG. 5), and a third heat exchange region over a side of the computing device. In this implementation, the processor 170 interfaces with a thermistor 180 thermally coupled to the digital display 330 to measure a temperature increase across the digital display 330 during operation of the device. When the processor 170 identifies a display temperature that exceeds a threshold temperature, the processor 170 manipulates one or more valves within first system 100 to move heated fluid from the first heat exchange layer over the display 330 to the second heat exchange layer 220 on the back of the device where heat is dissipated to the environment to cool the display 330. In one example, the processor 170 can thus control one or more valves within first system 100 to cool the digital display 330 during solar heating of the display 330, such as when the computing device is used in direct sunlight.

In yet another implementation, the processor 170 interfaces with a thermistor 180 thermally coupled to the electrical component 302 to measure the temperature of the electrical component 302. In one example, when the temperature of the electrical component 302 exceeds a threshold temperature, the processor 170 turns the displacement device 140 ‘ON’ to pump heated fluid from the internal heatsink 110 to the heat exchange layer 120, thereby cooling the electrical component 302. In another example, the processor 170 controls a fluid flow rate or ‘speed’ of the displacement device 140 based on the temperature of the electrical component 302, including increasing the displacement device 140 speed in response to a higher measured temperature at the electrical component 302 and decreasing the displacement device 140 speed in response to a lower measured temperature at the electrical component 302. In yet another example, the processor 170 dynamically and proportionally adjusts a clock speed of the electrical component 302 and the speed of the displacement device 140, thereby increasing heat flux through first system 100 proportionally with heat output of the electrical component 302 (which may be proportional to clock speed).

Because power consumption of an integrated circuit 302 (e.g., processor, microcontroller, display driver) can be proportional to computing power (e.g., load, clock speed) and temperature, first system 100 can, as in the foregoing implementation, cool the integrated circuit 302 to enable increased computing power without substantially sacrificing battery life in the computing device. Additionally or alternatively, first system 100 can cool a lower-capacity (e.g., cheaper) integrated circuit 302, thereby enabling the lower-capacity integrated circuit 302 to achieve a level computing power more comparable to a non-cooled, higher-capacity (e.g., more expensive) integrated circuit 302 without substantially sacrificing battery life of the computing device and/or a calendar life of the integrated circuit 302.

Similarly, in another implementation, the processor 170 interfaces with a thermistor 180 to detect a temperature of a battery 310 arranged within the computing device. In one example, when the temperature of the battery 310 exceeds a threshold temperature, the processor 170 sets valve states and turns the displacement device 140 ‘ON’ to move fluid through an internal heatsink arranged adjacent the battery 310 to cool the battery 310. In another example, the processor 170 controls a fluid rate or ‘speed’ of the displacement device 140 based on the temperature of the battery 310, including increasing flow rate through the displacement device 140 in response to higher measured battery 310 temperatures and decreasing flow rate through the displacement device 140 in response to lower measured battery temperatures. Thus, in this implementation, first system 100 can increase the charge rate, discharge rate, and/or improve a performance of a battery inside the computing device in the short term and improve a calendar life of the battery 310 in the long term by actively cooling the battery 310 as described above.

In a further implementation, the internal heatsink 110 includes a heat exchange region arranged on, adjacent, and/or proximal an internal speaker within the computing device, and the displacement device 140 moves heated fluid form the internal speaker to the heat exchange layer 120 over the display 330 to actively cool an electromechanical driver within the speaker. For example, when a user plays music or engages in a phone call through a speaker in the computing device, the processor 170 can set a state of one or more valves within first system 100 to route fluid through a second internal heat exchanger thermally coupled to the speaker, thereby cooling the speaker. Thus, in this implementation, first system 100 can enable the speaker to output louder, less distorted sound with better frequency response by cooling the electromechanical speaker driver within the speaker. First system 100 can additionally or alternatively enable a lower-quality (e.g., cheaper) speaker to output sound comparable to sound output by a higher-quality (e.g., more expensive) speaker by actively cooling the lower-quality speaker.

The fluid system can also include a pressure sensor fluidly coupled to the fluid (e.g., via the fluid junction 150), and the processor 170 can detect a leak in the fluid system and cut power to the displacement device 140 in response to an unexpected drop in fluid pressure. The processor 170 can also issue a warning or trigger an alarm, such as a visual warning shown on the display 330 of the computing device, to inform a user of such malfunction.

First system 100 can further include one or more air disturbers, such as a fan or a blower, configured to actively displace air over the heat exchange layer 120 to increase a rate of heat transfer from the heat exchange layer 120. However, the processor 170, the valve(s) 142, the internal heatsink 110, the heat exchange layer 120, the displacement device 140, and/or the air disturber(s) can be arranged in any other way on or in a computing device and can function in any other way to actively cool one or more electrical components within the computing device.

### 2. Second System and Applications

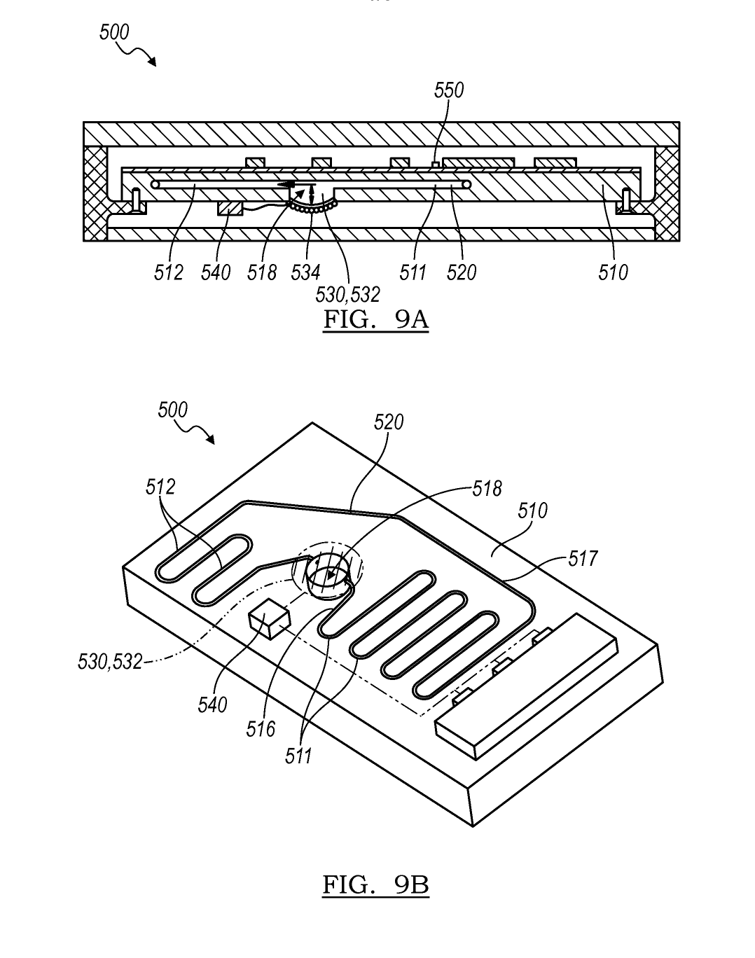

As shown in FIGS. 9A and 9B, a second system 500 for cooling an integrated circuit within a computing device includes: a substrate 510 arranged within the computing device, extending to an external housing of the computing device, and defining a closed fluid circuit including a cavity 518, a first boustrophedonic fluid channel 511, and a second boustrophedonic fluid channel 512, the first boustrophedonic fluid channel 511 defined across a first region of the substrate 510 adjacent the integrated circuit, and the second boustrophedonic fluid channel 512 defined across a second region of the substrate 510 proximal a perimeter of the substrate 510; a volume of fluid 520 within the closed fluid circuit; a displacement device 530 including a diaphragm 532 arranged across the cavity 518 and operable between a first position and a second position, the diaphragm 532 distended into the cavity 518 in the first position and distended away from the cavity 518 in the second position; and a power supply 540 powering the displacement device 530 to oscillate the diaphragm 532 between the first position and the second position to pump the volume of fluid 520 through the closed fluid circuit.

Similar to first system 100 described above, second system 500 functions to cool one or more electrical components within a computing device by circulating fluid through an internal structure (i.e., the substrate 510) within the computing device between a region proximal the electrical component to a region near a perimeter of the internal structure and/or adjacent a housing of the computing device. In particular, second system 500 functions to redistribute heat within the computing device by circulating fluid from a fluid channel near a heat source (i.e., the integrated circuit) to a fluid channel near a heat sink (e.g., the housing of the computing device) and then back again.

As described above, the computing device can be a cellular phone, a smartphone, a tablet, a laptop computer, a digital watch, a PDA, a personal music player, or any other suitable type of electronic and/or computing device that includes a display and an electrical circuit that outputs heat during operation.

### 2.1 Substrate 510

The substrate 510 of second system 500 is arranged within the computing device, extends to an external housing of the computing device, and defines a closed fluid circuit including a cavity, a first boustrophedonic fluid channel 511, and a second boustrophedonic fluid channel 512. The first boustrophedonic fluid channel 511 is defined across a first region of the substrate 510 adjacent the integrated circuit, and the second boustrophedonic fluid channel 512 is defined across a second region of the substrate 510 proximal a perimeter of the substrate 510. Generally, the substrate 510 is arranged within the computing device and defines a closed internal fluid circuit through which fluid can be pumped to redistribute thermal energy within the computing device. In particular, the substrate 510 conducts thermal energy (i.e., heat) from the integrated circuit (i.e., a heat source) into fluid within the first boustrophedonic fluid channel 511 and conducts thermal energy out of fluid within the second boustrophedonic fluid channel 512 proximal a perimeter of the substrate 510, such as into the housing of the computing device. The substrate 510 of second system 500 can therefore define a structure similar to the internal heatsink of first system S100 described above.

In one implementation, the substrate 510 defines a planar structure thermally, and a broad planar surface of the substrate 510 is thermally coupled to a printed circuit board supporting an integrated circuit within the computing device. In this implementation, the substrate 510 can define the first boustrophedonic fluid channel 511 under the integrated circuit. For example, the substrate 510 can define the first boustrophedonic fluid channel 511 adjacent and aligned with a footprint of the integrated circuit. Alternatively, the substrate 510 can define the first boustrophedonic fluid channel 511 that extends across a larger region of the planar structure, such as across a region of the planar structure adjacent multiple integrated circuits and/or other electrical components within the computing device such that fluid passing through the first boustrophedonic fluid channel 511 absorbs heat from the multiple integrated circuits and/or other electrical components before releasing this heat to a heat sink at the second boustrophedonic fluid channel 512.

Yet alternatively, the substrate 510 can define a third boustrophedonic fluid channel 513 fluidly coupled to the second boustrophedonic fluid channel 512 and adjacent a second electrical component (e.g., a second integrated circuit, a battery) such that fluid passing through the third boustrophedonic fluid channel 513 absorbs heat from the second electrical component before releasing this heat through the second boustrophedonic fluid channel 512 near a perimeter of the substrate 510. The substrate 510 can similarly define a second closed fluid loop including a third boustrophedonic fluid channel 513 fluidly adjacent a second electrical component (e.g., a second integrated circuit, a battery) and coupled to a fourth boustrophedonic fluid channel such that fluid passing through the third boustrophedonic fluid channel 513 absorbs heat from the second electrical component before releasing this heat through the fourth boustrophedonic fluid channel near a perimeter of the substrate 510.

In a similar implementation, the substrate 510 can be interposed between two printed circuit boards, each printed circuit board supporting an integrated circuit. In this implementation, the first boustrophedonic fluid channel 511 can extend across a region of the substrate 510 adjacent both the integrated circuits. Alternatively, the substrate 510 can define the first boustrophedonic fluid channel 511 adjacent a first integrated circuit arranged on the first printed circuit board, and the substrate 510 can define a third boustrophedonic fluid channel 513 adjacent a second integrated circuit arranged on the second printed circuit board, wherein the third boustrophedonic fluid channel 513 is fluidly coupled to the second boustrophedonic fluid channel 512 to form the closed fluid circuit with the first boustrophedonic fluid channel 511, or wherein the third boustrophedonic fluid channel 513 is coupled to a fourth boustrophedonic fluid channel to form a second discrete closed fluid circuit within the substrate 510.

The substrate 510 therefore defines the first (heat source) boustrophedonic fluid channel adjacent an electrical component within the computing device such that heat generated at the electrical component during operation of the computing device is communicated through the substrate 510 into fluid within the first boustrophedonic fluid channel 511. The substrate 510 therefore also defines a second (heat sink) boustrophedonic fluid channel proximal a perimeter of the substrate 510 such that heated fluid pumped into the second boustrophedonic fluid channel 512 is dumped into the outer region of the substrate 510, into the housing, or into another perimeter structure of the computing device, thereby cooling the fluid before the fluid returns to the first boustrophedonic fluid channel 511 to absorb more heat from the electrical component. The substrate 510 can also define other heat source boustrophedonic fluid channels adjacent other electrical components and fluidly coupled to the second boustrophedonic fluid channel 512 within the closed fluid circuit, or the substrate 510 can define other heat source boustrophedonic fluid channels adjacent other electrical components and fluidly coupled to another heat sink boustrophedonic fluid channel to define a second discrete closed fluid circuit. The first boustrophedonic fluid channel 511 can also define multiple parallel discrete fluid channels across the first region of the substrate 510, the discrete fluid channels terminating at manifolds at each end or terminating directly into the cavity 518; the second boustrophedonic fluid channel 512 can similarly define multiple parallel (or non-parallel) fluid channels across the second region of the substrate 510. However, the substrate 510 can define any other number of discrete or fluidly-coupled boustrophedonic fluid channels in any other arrangement within the computing device.

The first boustrophedonic fluid channel 511 can define a first density of parallel oscillating sections across the first region, such as in a sinusoidal or serpentine pattern, and the second boustrophedonic fluid channel 512 can define a second density of parallel oscillating sections across the second region, wherein the second density greater than the first density. In this implementation, the cross-sectional area of the first boustrophedonic fluid channel 511 can be greater that a cross-sectional area of the second boustrophedonic fluid channel 512 such that a flow velocity through the first boustrophedonic fluid channel 511 is less than a flow velocity through the second boustrophedonic fluid channel 512, thereby increasing a period of time during which a subvolume of fluid passes through a region of the substrate 510 adjacent the electronic component (or a substantially small footprint) and dispersing that fluid in the second boustrophedonic fluid channel 512 across a relatively large area of the substrate 510 near its perimeter. Alternatively, the first boustrophedonic fluid channel 511 can define a first cross-sectional area, and the second boustrophedonic fluid channel 512 can define a second cross-sectional area greater than the first cross-sectional area. However, the first and second (and other) boustrophedonic fluid channels can be of any other form, path, and/or cross-section and can be defined across corresponding areas of the substrate 510 of any other size or geometry.

The substrate 510 also defines a cavity between the first and second boustrophedonic fluid channels 511, 512, as shown in FIGS. 9A and 9B. Generally, the cavity 518 defines an interface between the diaphragm 532 of the displacement device 530 and the closed fluid circuit such that actuation of diaphragm moves fluid through the substrate 510. In one example, the cavity 518 couples directly to one end of the first boustrophedonic fluid channel 511 and directly to one end of the second boustrophedonic fluid channel 512, and opposite ends of the first and second boustrophedonic fluid channels 511, 512 connect to form the closed fluid circuit. In another example, the substrate 510 defines a supply conduit 516 and a return conduit 517 arranged between the first boustrophedonic fluid channel 511 and the second boustrophedonic fluid channel 512, and the cavity 518 is defined between and fluidly couples to the supply conduit 516 and the return conduit 517.

In one implementation in which the substrate 510 defines a planar structure (e.g., a planar sheet), the cavity 518 defines a cylindrical bore having an axis perpendicular to a broad face of the planar structure. In this example, the cavity 518 can thus be open on one side of the planar sheet, and the diaphragm 532 can be arranged across the open bore, thereby sealing the closed fluid circuit, such as shown in FIGS. 9A and 9B.

In another implementation, the substrate 510 defines a supply conduit 516 and a return conduit 517, each coupled at one end to the first boustrophedonic fluid channel 511 and at an opposite end to the second boustrophedonic fluid channel 512. In this implementation, the substrate 510 defines the cavity 518 in the form of a cross-over pipe or cross-over via between the supply conduit 516 and the return conduit 517, and the diaphragm 532 is arranged within the cross-over pipe or cross-over via to separate (i.e., seal) the supply conduit 516 from the return conduit 517. However, the substrate 510 can define the cavity 518 that is of any other form or geometry or fluidly coupled in any other way to the first and second boustrophedonic fluid channels 511, 512.

The cavity 518 can therefore fluidly couple to the first boustrophedonic fluid channel 511 at an inlet and can fluidly couple to the second boustrophedonic fluid channel 512 at an outlet. The inlet can further define an inlet vane extending toward the cavity 518, and the outlet can define an outlet vane extending away from the cavity 518 such that fluidly is preferentially displaced from the cavity 518 into the outlet as the diaphragm 532 transitions from the second position into the first position (e.g., as the diaphragm 532 lowers into the cavity 518) and such that fluidly is preferentially displaced from the inlet into the cavity 518 as the diaphragm 532 transitions from the first position into the second position (e.g., as the diaphragm 532 moves out of the cavity 518). However, the substrate 510 can define any other passive feature—or define the inlet, outlet, first and second boustrophedonic fluid channels 511, 512, or cavity of any other geometry—to induce unidirectional flow through the cavity 518 as the diaphragm 532 oscillates between the first and second positions.

Like the internal heatsink described above, the substrate 510 can be a metallic structure (e.g., aluminum, copper), a polymer structure, or a structure of any other suitable material. For example, the substrate 510 can include multiple layers (of the same material or dissimilar materials) stacked and bonded together to define the cavity 518 and the first and second boustrophedonic fluid channels 511, 512. In this example, a first layer of the substrate 510 can be cast from urethane with the cavity 518 and the first and second boustrophedonic fluid channels 511, 512 formed in situ as open structures, and a second cast or extruded layer can be bonded over the first layer to close the first and second boustrophedonic fluid channels 511, 512, thereby forming the substrate 510. The cavity 518 and the first and second boustrophedonic fluid channels 511, 512 can alternatively be machined, stamped, or otherwise formed into one or more sublayers, which are subsequently assembled to form the substrate 510. In a similar example, the substrate can be formed from two discrete sheets of aluminum—one or both defining open channels—that are braised together to close the open channels, thereby defining the first and second boustrophedonic fluid channels. However, the substrate 510 can be of any other thermally-conductive material manufactured in any other way to form the closed fluid loop.

The substrate 510 can be mounted to one or more structures within the computing device. For example, the substrate 510 can be mechanically fastened to the housing of the computing device. The substrate 510 can additionally or alternatively be bonded with thermally-conductive adhesive to the printed circuit board, to the housing, to a battery, or a back surface of display or touchscreen within the computing device. Additionally or alternatively, a portion of the substrate 510 can be arranged on and/or thermally coupled to a thermal plane within the device, or the substrate 510 can extend toward but be disconnected from the housing of the device and radiate (rather than conduct) thermal energy into the housing. However, the substrate 510 can be arranged or mounted in any other way within the computing device.

### 2.2 Volume of Fluid 520

The volume of fluid 520 of second system 500 is contained within the closed fluid circuit. Generally, the volume of fluid 520 functions to absorb thermal energy from a heat source within the computing device (i.e., the integrated circuit) and to discard thermal energy into another structure of the computing device (eh the housing) while circulating through the closed fluid circuit. For example, the volume of fluid 520 can be water, an alcohol, an oil (e.g., silicone oil), or a metallic fluid (e.g., Galinstan or mercury). However, the volume of fluid 520 can include any other one or more types of liquids or gases.

### 2.3 Displacement Device and Power Supply 540

The displacement device 530 of second system 500 includes a diaphragm arranged across the cavity 518 and operable between a first position and a second position, wherein the diaphragm 532 is distended into the cavity 518 in the first position and is distended away from the cavity 518 in the second position. Furthermore, the power supply 540 of second system 500 powers the displacement device 530 to oscillate the diaphragm 532 between the first position and the second position to pump the volume of fluid 520 through the closed fluid circuit.

Generally, the power supply 540 functions to supply power to the displacement device 530 to oscillate the position of the diaphragm 532 between the first and second positions, thereby varying the effective volume of the cavity 518 and pumping fluid between the first and second boustrophedonic fluid channels 511, 512. In particular, during operation, fluid is (preferentially) displaced from the cavity 518 into the second boustrophedonic fluid channel 512 as the diaphragm 532 moves into the first position, and fluid is displaced from the first boustrophedonic fluid channel 511 into the cavity 518 as the diaphragm 532 moves back into the second position. The power supply 540 continues to power the displacement device 530, thereby oscillating the diaphragm 532 back and forth between the first and second settings to induce fluid circulation within the closed fluid circuit.

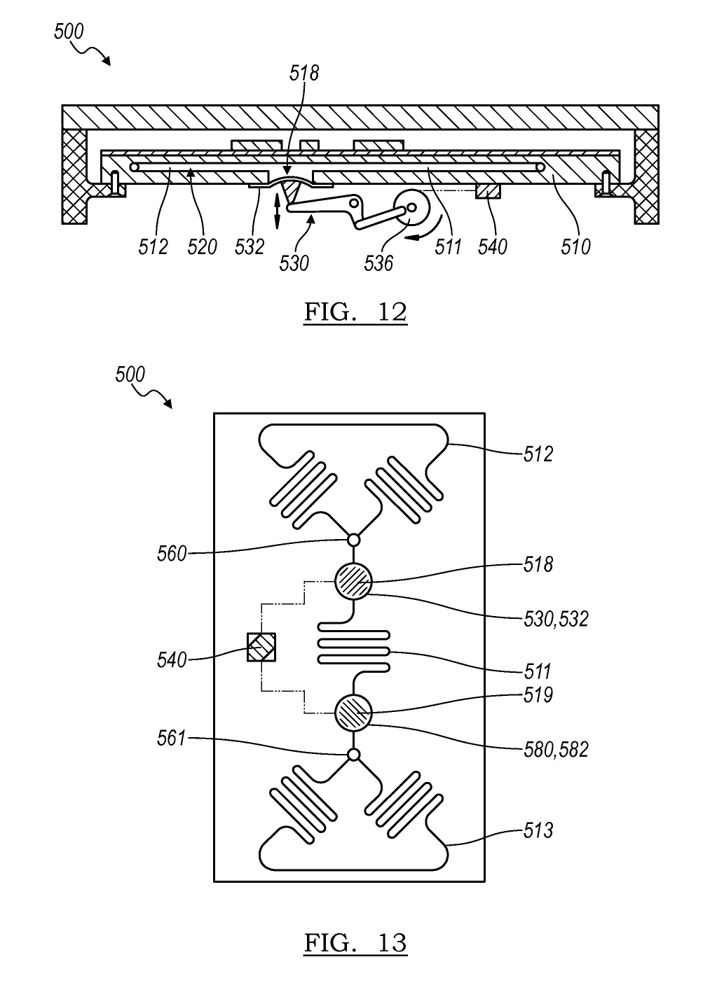

In one implementation, the displacement device 530 includes a piezoelectric layer 534 arranged over the diaphragm 532, and the power supply 540 oscillates a voltage potential across the piezoelectric layer 534 to pump fluid through the closed fluid circuit. For example, the power supply 540 can oscillate the voltage potential across the piezoelectric layer 534 between a low and a high voltage at a first frequency to induce a first flow rate of fluid through the closed fluid circuit, such as shown in FIG. 11. In this implementation, the power supply 540 can also adjust the oscillation frequency of the voltage potential across the piezoelectric layer 534 to adjust the flow rate. For example, as shown in FIG. 9A, second system 500 can include a temperature sensor 550 (e.g., a thermistor) thermally coupled to the integrated circuit, and the power supply 540 can increase the flow rate by decreasing (or increasing) the oscillation frequency as higher temperatures are measured at the integrated circuit by the temperature sensor 550. In this example, the power supply 540 can additionally or alternatively increase the voltage differential across the piezoelectric layer 534 to increase a magnitude of deflection of the diaphragm 532 between oscillations, thereby increasing a volume displacement per diaphragm oscillation cycle (and therefore a flow rate through the closed fluid circuit). The power supply 540 can also increase a voltage hold time across the piezoelectric layer 534 between voltage flips to similarly increase a magnitude of deflection of the diaphragm 532 between oscillations.

In the foregoing implementation, the piezoelectric layer 534 can be bonded over the diaphragm 532, grown onto the diaphragm 532, arranged between layers of the diaphragm 532, or coupled to the diaphragm 532 in any other suitable way.

In another implementation, the displacement device 530 includes a rotary actuator 536—such as an electromechanical rotary motor—coupled to the diaphragm 532 (near its center) via a bellcrank and connecting rod, as shown in FIG. 12. In this implementation, the power supply 540 provides power to the rotary actuator 536 to rotate the diaphragm 532, thereby deforming the diaphragm 532 between the first and second positions. In a similarly implementation, the displacement device 530 includes a rotary actuator 536 with an output shaft coupled to a cam in contact with the (center of the) diaphragm. Thus, as the power supply 540 provides power to the rotary actuator 536, a lobe of the cam cyclically depresses and releases the diaphragm 532 during rotation, thereby transitioning the diaphragm 532 between the first and second positions. The displacement device can alternatively include a pneumatic, hydraulic, electromagnetic, or other suitable type of actuator to drive the diaphragm between the first and second positions.

In the foregoing implementation and others, the displacement device can further include additional diaphragms (e.g., a second diaphragm and a third diaphragm), and the actuator within the displacement device can selectively transition the diaphragms between first and second positions to display fluid through the diaphragms (i.e., “stages”) of the displacement device (e.g., similar to a peristaltic pump). However, the displacement device 530 can include any other suitable type of actuator configured to oscillate the diaphragm 532 between the first and second positions in any other suitable way.

The diaphragm 532 is arranged over or within the cavity 518 and thus functions to seal the volume of fluid 520 within the closed fluid loop or to separate portions of the closed fluid loop. For example, in the implementation described above in which the cavity 518 defines a cylindrical bore with axis perpendicular to a broad face of the substrate 510, the diaphragm 532 can include an elastomer layer bonded to the broad face of the substrate 510 around the perimeter of the diaphragm 532. Alternatively, the diaphragm 532 can include an elastomer sheet of dimensions approximating the footprint of the substrate 510, and the elastomer sheet can be bonded fully across the substrate 510 and thus over the diaphragm 532. Thus, in this example, the diaphragm 532 can draw inward toward the cavity 518 during transitions into the first position, and the diaphragm 532 can draw outward from the cavity 518 during transitions into the second position.

In another example, in the implementation described above in which the substrate 510 defines the cavity 518 that is interposed between a supply conduit 516 and a return conduit 517, the diaphragm 532 can be arranged within the cavity 518, thereby fluidly isolating the supply conduit 516 from the return conduit 517, as shown in FIG. 11. In this example, the diaphragm 532 can draw toward the return conduit 517 during transitions into the first position and can draw toward the supply conduit 516 during transitions into the second position.

The diaphragm 532 can be chemically or mechanically bonded to the substrate 510, mechanically fastened to the substrate 510 (e.g., with machine screws), pressed into the cavity 518 with an interface fit, clamped into or over the cavity 518 (e.g., with a compression ring compressing the diaphragm 532 around a perimeter of the cavity 518), interposed between oversized seals or o-rings pressed into the cavity 518, or coupled to the cavity 518 (e.g., arranged within or arranged over the cavity 518) in any other suitable way. The diaphragm 532 can also be of a metallic, polymer, quartz, glass, or other material or combination of materials.

The power supply 540 can thus include a battery, a processor, a motor driver, a switch, a transistor, a clock, and/or any other suitable electrical component specific to second system 500 or integrated into the computing device to control actuation of the displacement device 530, such as described above.

However, the second system 500 can include any other suitable type of displacement device, such as described in U.S. patent application Ser. No. 14/081,519.

### 2.5 Valves

One variation of second system 500 includes one or more valves arranged along the closed fluid conduit to control fluid flow therethrough.

In one implementation, second system 500 includes a check (i.e., one-way) valve arranged between the first boustrophedonic fluid channel 511 and the second boustrophedonic fluid channel 512, wherein the check valve functions to retard fluid flow in a first direction through the closed fluid circuit and permits fluid flow through the closed fluid circuit in a second direction opposite the first direction, as shown in FIG. 11. Thus, as the power supply 540 actuates the displacement device 530 to oscillate the diaphragm 532, the check valve maintains unidirectional fluid flow through the closed fluid circuit and substantially prevents reverse flow. For example, the check valve can include a ball-type check valve, a diaphragm-type check valve, or any other suitable type of check valve. The check valve can also be arranged within the first boustrophedonic fluid channel 511, within the second boustrophedonic fluid channel 512, at an inlet or outlet of the cavity 518, or in any other location along the closed fluid circuit.

In another implementation, second system 500 includes a first valve 560 arranged between the first boustrophedonic fluid channel 511 and the cavity 518 and a second valve 561 arranged between the cavity 518 and the second boustrophedonic fluid channel 512, as shown in FIG. 11. In this implementation, the first and second valves 560, 561 can be check valves, as described above, and oriented along the closed fluid circuit to maintain unidirectional fluid flow there through (i.e., with an outlet of the first valve 560 pointing toward an inlet of the second valve 561). Alternatively, the first and second valves 560, 561 can be actuated electromechanically, and the power supply 540 can selectively open and close the first and second valves 560, 561 (phased at 180°) in time (e.g., in phase) with oscillations of the diaphragm 532. For example, the power supply 540 can control the displacement device 530 and the first and second valves 560, 561 such that the first valve 560 opens and the second valve 561 closes as the diaphragm 532 begins to transition from the first position to the second position (i.e., as the effective volume of the cavity 518 begins to decrease and such that the first valve 560 closes and the second valve 561 opens as the diaphragm 532 beings to transition from the second position to the first position (i.e., as the effective volume of the cavity 518 begins to increase).

In the foregoing implementation, the power supply 540 can also adjust the phase of actuation of the second valve 561 relative to the first valve 560 and/or phases of actuation of the first and second valves 560, 561 relative to actuation of the diaphragm 532. For example, when the displacement device 530 is actuated at a first (low) frequency, the first valve 560 can begin to open and the second valve 561 can begin to close just as the diaphragm 532 reaches a “bottom dead center” in the first position. However, in this example, when the displacement device 530 is actuated at a second frequency greater than the first, the first valve 560 can begin to open and the second valve 561 can begin to before the diaphragm 532 reaches bottom dead center in the first position such that the first valve 560 is fully open and the second valve 561 is fully closed once the diaphragm 532 reaches bottom dead center and begins transition back into the second position, thereby drawing fluid from the first boustrophedonic fluid channel 511 into the cavity 518. Specifically, in this example, the first valve 560 can be opened at a phase of ˜0° and the second valve 561 can be actuated at a phase of ˜180° at a low diaphragm oscillation frequency, and the first valve 560 can be opened at a phase of—10° and the second valve 561 can be actuated at a phase of ˜170° at a high(er) diaphragm oscillation frequency. However, in this implementation, the power supply 540 can control the first and second valves 560, 561 and the displacement device 530 in any other suitable way.

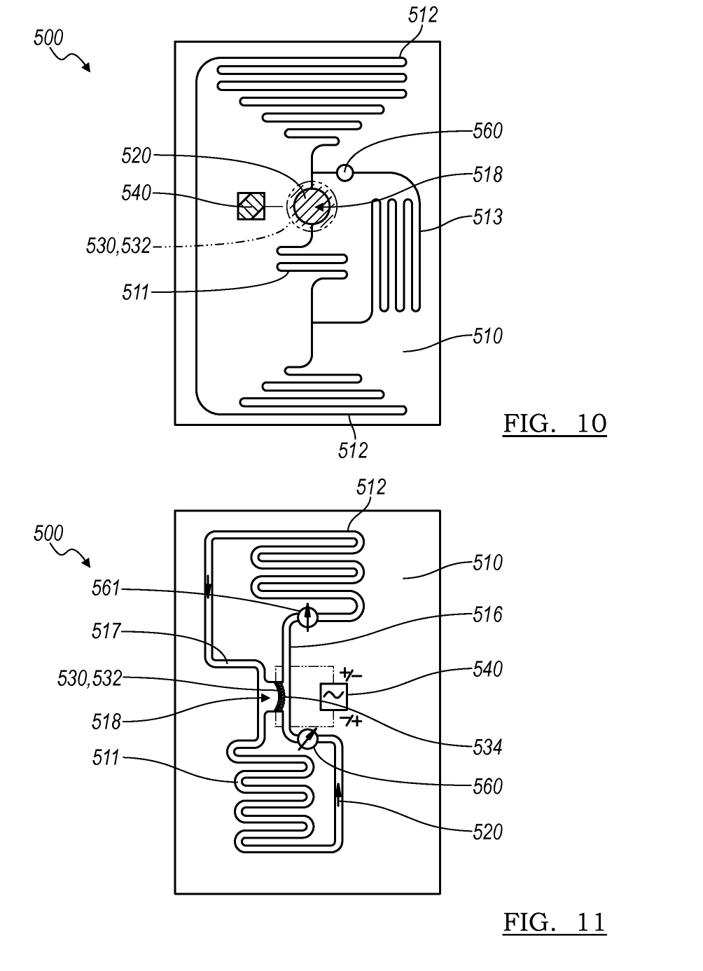

In yet another implementation, the substrate 510 includes a third boustrophedonic fluid channel 513 fluidly coupled to the first and second boustrophedonic fluid channels 511, 512 by a controllable valve 560, as shown in FIGS. 10 and 13. In one example implementation, the third boustrophedonic fluid channel 513 is arranged over a heatsink region of the substrate 510 near a perimeter of the substrate 510, and the valve 560 includes a dual-outlet electromechanical valve with an inlet coupled to an outlet of the cavity 518, a first outlet coupled to an inlet of the second boustrophedonic fluid channel 512, and a second outlet coupled to an inlet of the third boustrophedonic fluid channel 513. In this example implementation, the valve 560 can be selectively transitioned between a first state and a second state, wherein the second boustrophedonic fluid channel 512 is opened to and the third boustrophedonic fluid channel 513 is closed to the cavity 518 in the first state, and wherein the second boustrophedonic fluid channel 512 is opened to and the third boustrophedonic fluid channel 513 is closed to the cavity 518 in the second state. In this example implementation, the valve 560 can thus be actuated to selectively open and close boustrophedonic fluid channels over heatsink areas of the substrate 510 to control distribution of thermal energy from the integrated circuit into other regions of the substrate 510 and thus into various regions (e.g., surfaces) of the computing device. For example, as described above, the valve 560 can be controlled to selectively distribute fluid through portions of the closed fluid circuit based on an orientation of the computing device, such as to distribute heat from the integrated surface to a region of the substrate 510 adjacent an exterior surface of the computing device where a user's hand is expected not to be in the present orientation of the computing device.

In a similar example implementation, the valve 560 can be arranged within the closed fluid loop to selectively open and close the third boustrophedonic fluid channel 513 to the first and second boustrophedonic fluid channels 511, 512, such as to selectively increase and decrease the length of the closed fluid loop. For example, as described above, the valve 560 can be closed to maintain fluid flow only through the first and second boustrophedonic fluid channels 511, 512 when the temperature of the integrated circuit is below a threshold temperature, thereby limiting a pressure required to move fluid at a particular flow rate through the closed fluid loop. In this example, the valve 560 can then be opened to permit fluid to also flow through the third boustrophedonic fluid channel 513, thereby increasing the length of the closed fluid circuit and the cooling capacity of second system 500, albeit at a higher required fluid pressure to maintain the particular flow rate. The valve 560 can thus be controlled based on a detected temperature of the integrated circuit.

The substrate 510 can additionally or alternatively define a fourth boustrophedonic fluid channel over a heat source region of the substrate 510, such as adjacent a second integrated circuit, as described above. Second system 500 can thus also include a valve similarly controlled to control fluid flow through the fourth boustrophedonic fluid channel to control (e.g., selectively reduce) the temperature of the second integrated circuit. However, second system 500 can include any other valve passively or actively operated in any other way to control fluid flow through the closed fluid loop.

### 2.6 Second Displacement Device 580

As shown in FIG. 13, in one variation of second system 500, the closed fluid circuit includes a second cavity 519, a supply conduit 516 communicating fluid from the first boustrophedonic fluid channel 511 to the second boustrophedonic fluid channel 512, and a return conduit 517 communicating fluid from the second boustrophedonic fluid channel 512 to the first boustrophedonic fluid channel 511. The cavity 518 is defined in the substrate 510 along the supply conduit 516, and the second cavity 519 defined in the substrate 510 along the return conduit 517. In this variation, second system 500 also includes a second displacement device 580 including a second diaphragm 581 arranged across the second cavity 519 and operable between a first position and a second position, the second diaphragm 581 distended into the second cavity 519 in the first position and distended away from the second cavity 519 in the second position. Generally, in this variation, second system 500 includes a second displacement device 580 that cooperates within the (first) displacement device to pump fluid through closed fluid loop. For example, the power supply 540 can power the displacement device 530 and the second displacement device 580 at a phase of 180° such that the diaphragm 532 is in the first position when the second diaphragm 581 is in the second position and such that the diaphragm 532 is in the second position when the second diaphragm 581 is in the first position. However, second system 500 can include any other type and number of displacement devices arranged in any other way within the computing device to include fluid flow through the closed fluid circuit.

### 2.7 Heat Exchange Layer

As described above, the substrate 510 of second system 500 can incorporate similar structures and yield similar functions as the internal heatsink of first system 100 described above. One variation of second system 500 can therefore include a heat exchange layer arranged across a viewing surface of a digital display of the computing device, and the closed fluid circuit of the substrate 510 can fluidly couple to the heat exchange layer to redistribute thermal energy from the integrated circuit to an external surface of the computing device, such as over a display integrated in to the computing device. For example, as described above, the heat exchange layer can be of a transparent material and define a fluid channel extending across a portion of the digital display. In this example the fluid channel can include a fluid inlet fluidly coupled to the second boustrophedonic fluid channel 512 and a fluid outlet fluidly coupled to the first boustrophedonic fluid channel 511. Thus fluid channel of the heat exchange layer and the cavity 518, the first boustrophedonic fluid channel 511, and the second boustrophedonic fluid channel 512, etc. of the substrate 510 can thus define the closed fluid circuit. However, second system 500 can include any other suitable type or form of heat exchanger, and fluid structures within the substrate 510 can fluidly couple to any one or more heat exchanges within the device to distribute thermal energy away from the integrated circuit (and to dissipate this thermal energy to the environment).

As a person skilled in the art will recognize from the previous detailed description and from the figures and claims, modifications and changes can be made to the preferred embodiments of the invention without departing from the scope of this invention as defined in the following claims.

We claim:

1. A system for cooling an integrated circuit within a computing device including a digital display, the system comprising:
an internal heatsink thermally coupled to the integrated circuit and defining a fluid passage comprising a first end and a second end;
a heat exchange layer arranged across a viewing surface of the digital display, comprising a transparent material, and defining a fluid channel extending across a portion of the digital display, the fluid channel comprising a fluid inlet coupled to the first end of the fluid passage and a fluid outlet coupled to the second end of the fluid passage;
a transparent fluid; and
a displacement device configured to circulate the transparent fluid between the internal heatsink and the fluid channel.

2. The system of claim 1, wherein the heat exchange layer comprises a glass substrate bonded to a touch sensor arranged over the digital display, the glass substrate and the touch sensor layer cooperating to define the fluid channel.

3. The system of claim 2, further comprising a pressure relief valve arranged between the internal heatsink and the heat exchange layer and configured to open in response to fluid pressure in the fluid channel exceeding a threshold pressure.

4. The system of claim 1, wherein the heat exchange layer is arranged over the digital display defining a rectangular viewing area, the fluid channel extending across the digital display with the fluid inlet proximal a first short edge of the rectangular viewing area and the fluid outlet proximal a second short edge of the rectangular viewing area opposite the first short edge.

5. The system of claim 4, wherein the heat exchange layer defines a second fluid channel comprising a second fluid inlet and a second fluid outlet fluidly coupled to the internal heatsink, the second fluid channel extending across the digital display with the second fluid inlet proximal a first long edge of the rectangular viewing area and the second fluid outlet proximal a second long edge of the rectangular viewing area opposite the first long edge.

6. The system of claim 5, wherein the displacement device is configured to circulate the transparent fluid between the internal heatsink and the fluid channel when the computing device is oriented with the rectangular viewing area in a landscape position and to circulate the transparent fluid between the internal heatsink and the second fluid channel when the computing device is oriented with the rectangular viewing area in a portrait position.

7. The system of claim 6, wherein the displacement device comprises a valve arranged between the fluid channel and the second fluid channel, and further comprising a processor configured to set a position of the valve in response to an output of a motion sensor arranged within the computing device.

8. The system of claim 5, wherein the displacement device is configured to selectively circulate the transparent fluid between the internal heatsink and the fluid channel and between the internal heatsink and the second fluid channel based on a temperature gradient across the computing device.

9. The system of claim 1, further comprising a second heat exchange layer arranged across ventral exterior surface of the computing device opposite the digital display, the second heat exchange layer defining a second fluid channel fluidly coupled to the first fluid channel, wherein the displacement device is configured to circulate the transparent fluid between the fluid channel and the second fluid channel when a temperature of the digital display exceeds a threshold temperature.

10. The system of claim 1, wherein the heat exchange layer defines a set of parallel fluid channels, an inlet manifold, and an outlet manifold, the set of fluid channels comprising the fluid channel, and each fluid channel in the set of fluid channels originating at the inlet manifold and terminating at the outlet manifold.

11. The system of claim 10, wherein the inlet manifold and the outlet manifold are arranged over a bezel area of the computing device adjacent a viewing area of the digital display.

12. The system of claim 1, further comprising:
a substrate of a substantially transparent material, arranged over the heat exchange layer opposite the display, and defining a second fluid channel and a fluid conduit fluidly coupled to the second fluid channel, the second fluid channel fluidly decoupled from the fluid channel,
a tactile layer of a substantially transparent material and comprising a peripheral region coupled to the substrate and a deformable region arranged over the fluid conduit and disconnected from the substrate, and
a second displacement device coupled to the second fluid channel and configured to displace fluid through the fluid channel to transition the deformable region from a retracted setting to an expanded setting, the deformable region elevated above the peripheral region in the expanded setting.

13. The system of claim 1, wherein the heat exchange layer comprises a substrate and an elastomer layer, the substrate defining an open trough extending across a surface of the substrate, and the elastomer layer comprising a peripheral region coupled to the surface of the substrate and a deformable region arranged over the open trough to define the fluid channel, wherein the deformable region is configured to expand outwardly above the peripheral region in response to increased fluid pressure within the fluid channel.

14. The system of claim 1, wherein the displacement device is configured to circulate the transparent fluid between the internal heatsink and the fluid channel at a working pressure corresponding to a measured temperature of the integrated circuit.

15. The system of claim 1, wherein the displacement device and the internal heatsink cooperate to define a passive heat pipe.

16. The system of claim 1, wherein the heat exchange layer comprises a transparent elastomer of a first refractive index at a wavelength of light, and wherein the transparent fluid comprises an oil of a second refractive index substantially similar to the first refractive index at the wavelength of light.

17. The system of claim 1, wherein the internal heatsink comprises a shell configured to cooperate with a printed circuit board within the computing device to enclose the integrated circuit, wherein the displacement device is configured flood the integrated circuit with transparent fluid.

18. The system of claim 1, wherein the internal heatsink comprises a metallic structure configured to shield electromagnetic interference from the integrated circuit.

19. The system of claim 1, wherein the internal heatsink defines a series of internal vanes within the fluid channel adjacent the integrated circuit, the vanes extending substantially parallel to a direction of flow of the transparent fluid through the fluid passage.

20. A system for cooling an electrical component within a computing device including a digital display, the system comprising:
an internal heatsink thermally coupled to the electrical component and defining a fluid passage comprising a first end and a second end;
a heat exchange layer arranged over the digital display, comprising a transparent material, defining a first fluid channel cooperating with the internal heatsink to define a first fluid circuit, and defining a second fluid channel cooperating with the internal heatsink to define a second fluid circuit;
a transparent fluid; and
a displacement device configured to circulate the transparent fluid within the first circuit in response to detected orientation of the computing device in a first position and to circulate the transparent fluid within the second circuit in response to detected orientation of the computing device in a second position.

21. The system of claim 20, wherein the displacement device comprises a valve arranged between the first fluid channel and the second fluid channel, and further comprising a sensor and a processor, the processor configured to detect an orientation of the computing device based on an output of the sensor and to set a position of the valve based on a detected orientation of the computing device.

22. The system of claim 20, wherein the displacement device is configured to circulate the transparent fluid within the first circuit in response to detected orientation of the computing device in the first position approximating a landscape orientation, and wherein the displacement device is configured to circulate the transparent fluid within the second circuit in response to detected orientation of the computing device in the second position approximating a portrait orientation.

23. The system of claim 20, wherein the first fluid channel extends over the viewing area of the display, and wherein the second fluid channel extends over a bezel adjacent a viewing area of the display.

24. A system for cooling an integrated circuit within a computing device, the system comprising:
an internal heatsink thermally coupled to the integrated circuit and defining a fluid passage comprising a first end and a second end;
a heat exchange layer arranged across an external surface of the computing device, and defining a fluid channel, the fluid channel comprising a fluid inlet coupled to the first end of the fluid passage and a fluid outlet coupled to the second end of the fluid passage;
a fluid; and
a displacement device configured to circulate the fluid between the internal heatsink and the fluid channel.

25. The system of claim 24, wherein the heat exchange layer across an opaque area of the computing device and a viewing surface of a digital display within the computing device, and wherein the fluid channel extends across a portion of the digital display.
